(19) United States
(12) Patent Application Publication
(10) Pub. No.: US 2026/0213124 A1
(43) Pub. Date: Jul. 23, 2026

(54) Measurement Method and Charged Particle Beam Device

(71) Applicant: Hitachi High-Tech Corporation, Minato-ku, Tokyo (JP)

(72) Inventor: Kazufumi MATSUKURA, Tokyo (JP)

(21) Appl. No.: 19/138,887

(22) PCT Filed: Dec. 21, 2022
(86) PCT No.: PCT/JP2022/047085

§ 371 Date: Jun. 13, 2025

(51) Int. Cl. H01J 37/28; H01J 37/07

(52) U.S. Cl. CPC H01J 37/28; H01J 37/07; H01J 2237/2001; H01J 2237/20235; H01J 2237/24564

(57) ABSTRACT

An object of the invention is to provide a measurement technique capable of reducing an influence of drift of a probe position without using position information of the probe. A measurement method according to the invention includes: measuring, by a charged particle beam device, a displacement of a probe generated under a temperature condition when a sample is observed using the charged particle beam device; and specifying, by using a result of the measurement, a movement amount by which the probe is moved to offset the displacement (see FIG. 2).

### TECHNICAL FIELD

The present invention relates to a method for measuring electrical characteristics by bringing a probe into contact with a sample.

### BACKGROUND ART

A scanning electron microscope (SEM) is a device that observes a sample by irradiating the sample with a charged particle beam (for example, an electron beam). Further, a device provided with a probe that comes into contact with the sample to measure electrical characteristics of the sample is called an SEM nanoprober and the like. In the device, it is necessary to correct an influence of drift in which a position (particularly, a position in a height direction) of the probe is shifted.

PTL 1 below describes an inspection device including a probe that comes into contact with a sample. This literature describes a technique that “The inspection device according to Claim 1 or 2 includes: a Z-sensor that measures the height of the sample mounted on the sample stage; and a temperature sensor that measures the temperature of the sample. A change in the height of the sample caused by a change in the temperature of the sample is canceled by moving the probe with the sample stage and the probe unit.” (see Claim 5).

### CITATION LIST

### Patent Literature PTL 1: JP2008-157650A

### SUMMARY OF INVENTION

### Technical Problem

When a position sensor is mounted in a sample chamber or a probe unit is changed in design to mount the position sensor in order to acquire position information of the probe, an image quality of an observation image of the sample may be deteriorated. This is because the arrangement of the position sensor increases an area of an object that blocks the charged particle beam with which the sample is irradiated for sample observation. In this case, in particular, it is difficult to perform probing (work of bringing the probe into contact with the sample) while observing at a high magnification.

Therefore, when the drift of the probe is corrected, it is useful when the correction can be implemented without using information on a current position of the probe. However, in the related art such as PTL 1, since it is assumed that the position information of the probe is measured by the Z-sensor, it is difficult to satisfy this need.

The invention has been made in view of the above problems, and an object of the invention is to provide a measurement technique capable of reducing an influence of drift of a probe position without using position information of the probe.

### Solution to Problem

A measurement method according to the invention includes: measuring, by a charged particle beam device, a displacement of a probe generated under a temperature condition when a sample is observed using the charged particle beam device; and specifying, by using a result of the measurement, a movement amount by which the probe is moved to offset the displacement.

### Advantageous Effects of Invention

According to a measurement method of the invention, an influence of drift of a probe position can be reduced without using position information of the probe. Problems, configurations, effects, and the like other than those described above will become apparent by description of the following embodiments.

### BRIEF DESCRIPTION OF DRAWINGS

FIG. 1 shows an overall configuration diagram of a charged particle beam device 100.

FIG. 2 is a flowchart showing a procedure for calculating a correction value for correcting drift of a probe 15.

FIG. 3 is a flowchart showing a procedure for measuring electrical characteristics of a sample.

FIG. 4 is an example of a screen of a user interface provided by a control computer 23 in S205.

### DESCRIPTION OF EMBODIMENTS

### Embodiment 1

In Embodiment 1 of the invention, a configuration example will be described in which, in a nanoprober (charged particle beam device) for evaluating an electrical characteristic of a sample, after a probe is brought into contact with the sample, a drift amount, that is a problem when the contact is maintained for a long time, is observed by an SEM image.

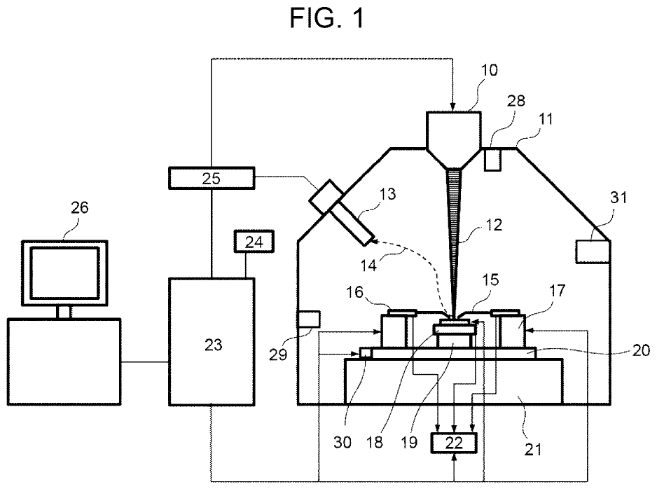

FIG. 1 is an overall configuration diagram of a charged particle beam device 100 according to Embodiment 1. An electron gun 10 forms an irradiation optical system for irradiating and scanning a sample 27 with a primary electron beam 12. Therefore, the electron gun 10 includes all elements necessary for electron irradiation, such as an electron source for generating an electron beam and a deflection lens for scanning a beam. A separation wall 11 of a vacuum chamber separates an atmospheric pressure region from a vacuum region in the vacuum chamber. An operation of the electron gun 10, for example, an electron beam extraction voltage of the electron source and a voltage applied to the deflection lens are controlled by an electron gun controller 25. Secondary electrons 14 generated from the sample 27 by the irradiation of the primary electron beam 12 are detected by a secondary electron detector 13. In the secondary electron detector 13, a sensor portion that actually detects electrons is disposed in the separation wall 11, but a root portion to which a wiring and the like for power supply connection is connected protrudes outside the separation wall 11. The control computer 23 creates an observation image based on a detection result of the secondary electrons 14. The observation image can be observed on an operator operation unit 26.

The probe 15 is a probe to be brought into contact with a predetermined region of a sample to be inspected, and is held by a probe holder 16. A probe unit 17 is a device for moving the probe holder 16 to a desired position, and moves the probe 15 together with the probe holder 16 to the desired position. The probe unit 17 includes a drive unit in an xy direction (in-plane) and a z direction (perpendicular). A camera 28 disposed above and a camera 29 disposed in a lateral direction can observe the probe 15. Observation by each camera is mainly used when roughly adjusting the probe. Fine adjustment and an operation at the moment of contact with the sample can be performed while an operator observes the SEM image of the probe 15 on the operator operation unit 26, or can be automatically controlled by the control computer 23.

The sample 27 to be actually inspected for defects is held on a sample stand 18. The sample stand 18 is further held by a sample stand drive unit 19, and the sample stand 18 and the sample stand drive unit 19 are collectively referred to as a device under test (DUT) stage. The DUT stage and the probe unit 17 are formed on a large sample stage 20. The large sample stage 20 includes a drive unit in the xy direction (in-plane) and the z direction (perpendicular). The large sample stage 20 is disposed on a base 21, and is moved in the xy direction (in-plane) and the z direction (perpendicular) by a drive unit. Accordingly, a relative position between the primary electron beam 12 and the sample 27 can be changed without changing the relative position between the DUT stage and the probe unit 17.

Operations of the electron gun controller 25, the secondary electron detector 13, the probe unit 17, the DUT stage, and the large sample stage 20 are controlled by the control computer 23. The sample stand 18 and the probe holder 16 are connected to an electrical characteristic measurement instrument 22. Since the probe 15 and the probe holder 16 touch the sample 27 to detect an electric signal, the probe 15 and the probe holder 16 are electrically floating except for the electrical characteristic measurement instrument 22. The electrical characteristic measurement instrument 22 mainly measures a current and voltage characteristic of the sample 27 detected by the probe 15 and calculates a desired electrical characteristic value from the measurement, and calculates, for example, a resistance value, a current value, a voltage value, and the like of a contact point of the probe 15.

A characteristic value measured by the electrical characteristic measurement instrument 22 is transmitted to the control computer 23 via a transmission line. The control computer 23 performs more advanced analysis based on transmitted information. For example, a measurement value is analyzed to determine whether a measurement portion is defective or normal. The control computer 23 includes a storage unit 24 such as an optical disk, a hard disk, and a memory, and can store the measured electrical characteristic. The control computer 23 also plays a role of controlling an operation of the entire charged particle beam device 100. The control computer 23 includes the storage unit 24 for storing software for controlling each connected component, and an input unit for a device user to input various setting parameters of the device. Examples of the input unit include an image display unit for displaying an operation screen and an SEM image, a keyboard, and a mouse for moving a pointer on the operation screen.

The large sample stage 20 is provided with a heating unit 30, and the separation wall 11 is provided with a cooling unit 31. The heating unit 30 and the cooling unit 31 are connected to the control computer 23 and are controlled in operation by the control computer 23.

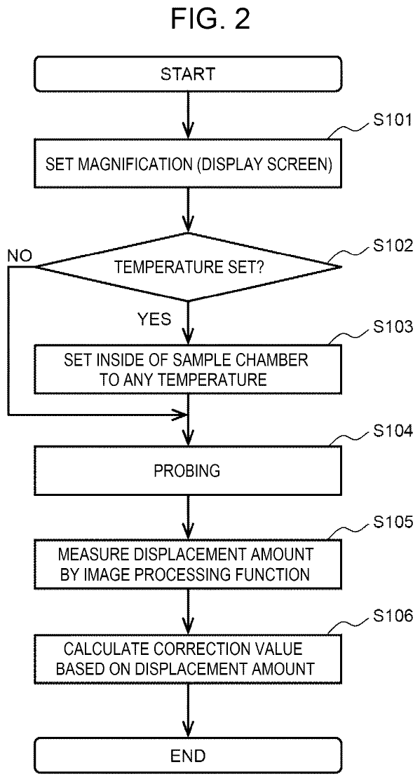

FIG. 2 is a flowchart showing a procedure for calculating a correction value for correcting drift of the probe 15. This flowchart can be commonly used in any of (a) a case where the measurement is performed at a room temperature without heating or cooling the sample, (b) a case where the measurement is performed after heating the sample, and (c) a case where the measurement is performed after cooling the sample. The difference therebetween will be described later.

### (FIG. 2: Step S101)

When the charged particle beam device 100 is activated, the charged particle beam device 100 enters a setting magnification waiting state of the SEM image, and a magnification setting input unit is displayed on a display screen associated with the control computer 23. The magnification setting input unit is, for example, an input unit using an icon or a graphical user interface (GUI). A user inputs a magnification of the SEM by the input unit. The control computer 23 adjusts conditions of the electron gun 10 based on an input value, acquires an SEM image at the input magnification, and displays the SEM image on the operator operation unit 26. The user visually checks whether a target measurement position of the sample is included in the acquired SEM image. If not, the large sample stage 20 is driven to move the sample stand 18 into a field of view of the SEM image. Instead of the large sample stage 20, the DUT stage itself may be moved to move a portion to be inspected into the field of view of the SEM image. Depending on a size of the portion to be inspected, when the magnification of the SEM is increased, an enlarged image of the portion to be inspected is displayed, so that the user can perform probing on the portion to be inspected of the sample.

### (FIG. 2: Steps S102 to S103)

The user instructs the control computer 23 whether to evaluate a temperature characteristic of the sample. When the temperature characteristic is evaluated (S102: YES), the inside of the sample chamber is heated or cooled to a desired temperature by the heating unit 30 or the cooling unit 31 (S103). When the temperature adjustment is unnecessary (S102: NO, that is, when measurement is performed at the room temperature), the processing skips to S104.

### (FIG. 2: Step S104)

The user operates the operator operation unit 26 to bring the probe 15 into contact with the portion to be inspected. This work may be performed manually by the user, or may be automatically performed by the control computer 23 according to a predetermined movement amount. In this step, the probe 15 is moved onto the portion to be inspected, and the probe 15 is moved downward in a Z-axis direction, thereby bringing the probe 15 into contact with the portion to be inspected.

### (FIG. 2: Step S105)

When the probe 15 is in contact with the portion to be inspected, this step and subsequent steps are started. After the probe 15 is in contact with the sample 27, the control computer 23 generates SEM images of the probe 15 at predetermined time intervals and analyzes the SEM images to calculate a drift amount (displacement amount) of a tip end of the probe 15 at the predetermined time intervals. The control computer 23 stores the displacement amount for each time interval into the storage unit 24.

### (FIG. 2: Step S106)

Based on the drift amount calculated in S105, the control computer 23 calculates a correction amount to be given to the probe 15 while measuring the electrical characteristic of the sample 27 (S106). A specific example of the calculation procedure will be described later. The control computer 23 stores the calculated correction value into the storage unit 24.

### (FIG. 2: Steps S105 to S106: Supplement)

A time length (synonymous with a measurement time T described later) for performing S105 to S106 may be designated by the user on, for example, the screen of S101, or may be automatically determined by the control computer 23 according to a type of a sample to be observed.

A procedure for calculating the correction value (during room temperature measurement) in S106 will be described. At the room temperature, the drift of the probe 15, which is mainly called a creep phenomenon, caused by a potential strain of a piezoelectric element that is an actuator of the probe unit 17, is corrected. The drift due to the creep phenomenon refers to a phenomenon in which drift of about 10% of the immediately previous movement amount occurs in the same direction as the immediately previous movement direction. Since the probe 15 is brought into contact the sample 27 by moving the probe 15 in a Z-axis downward direction (direction approaching the sample 27), drift occurs in the Z-axis downward direction. Accordingly, after the sample 27 and the probe 15 are in contact with each other, a pressure is applied to the sample 27, the probe 15 is bent, and a displacement occurs toward the tip end of the probe 15 when viewed on the SEM image (upper viewpoint). When the drift amount exceeds a range of the portion to be inspected, the contact between the probe 15 and the portion to be inspected is lost. The correction value is determined such that the tip end of the probe keeps contact for the measurement time T determined by the user within the range of the portion to be inspected.

The drift amount of the probe at a certain time interval of t seconds is Ap, and the measurement time is T. After n minutes from the contact of the probe 15 with the portion to be inspected, the probe 15 is retracted {Σ(t=1, n)Δp}−a in a Z-axis upward direction. The correction value a is a correction value for preventing the contact between the probe 15 and the sample 27 from being lost when the probe 15 is excessively retracted in the upward direction. As Δp, the same value may be used for each time interval, or an actual measurement value for each time interval measured from the observation image of the probe 15 may be used.

After (n+1) minutes (that is, one minute after the upward retraction), the probe 15 is moved to the Z-axis downward direction by 10% (({Σ(t=1, n)Δp}−a)×0.1) of an upward retraction amount at the time point after n minutes. This is for re-correcting creep drift due to the upward retraction based on the principle that the drift due to the creep phenomenon occurs in the same direction by about 10% of the immediately previous movement amount.

The correction value a is set in advance within a range in which desired measurement accuracy can be maintained, and is stored in advance in the storage unit 24 and the like. The correction value a may be changed according to a size of the portion to be inspected and the measurement time. The same applies to correction values b and c described later.

n can be designated by the user within a range of a time length T on, for example, the screen of the S101, as a timing at which the correction is performed. The user can similarly designate a time interval t. The values of n and t may be different for each probe or may be common for all probes. The same applies to the following embodiments.

### Embodiment 2

In Embodiment 2 of the invention, a procedure for determining a drift correction value in a case where measurement is performed after heating the sample 27 will be described. Since the configuration of the charged particle beam device 100 is the same as that of Embodiment 1, a method for obtaining a correction value during heating will be mainly described below.

During heating, in addition to the drift due to the creep phenomenon at the room temperature, drift due to mechanical strain caused by heat is also corrected. The drift due to the mechanical strain caused by heat occurs in the Z-axis downward direction in the probe 15, and occurs in the Z-axis upward direction in the sample stand drive unit 19. Therefore, since a pressure applied by the probe 15 to the portion to be inspected is strong, the drift of the tip end of the probe during heating is larger than the drift at the room temperature. When the drift amount exceeds the range of the portion to be inspected, the contact between the probe and the portion to be inspected is lost. The correction value is determined such that the tip end of the probe keeps contact for the measurement time T determined by the user within the range of the portion to be inspected.

A drift amount of the sample stand drive unit 19 in the certain time interval of t seconds in the Z-axis upward direction due to heat is Δs, and a measurement time is T. The tip end of the probe drifts in a probe tip end direction by (Δp+Δs) in each certain time interval of t seconds. Therefore, after n minutes have elapsed from the contact of the probe 15 with the portion to be inspected, the probe 15 is retracted to the upward direction by (Δp+Δs−b) in each time interval of t seconds. b is a correction value for preventing contact with the sample 27 from being lost when the probe is retracted beyond an initial position.

Even when the sample 27 is heated, creep drift of the actuator occurs. However, since the thermal drift caused by heating is considerably larger than the creep drift, the influence of the creep drift can be substantially ignored. Therefore, in the embodiment, re-movement for re-correcting new creep drift generated by retracting the probe 15 to the upward direction is not performed. Similarly, even in the case of cooling the sample 27 described later, re-movement for re-correction is not performed.

Since the thermal drift generated by heating the sample 27 is larger than the creep drift and the influence thereof is remarkable, the drift correction is performed in each time interval of t seconds in the embodiment, unlike Embodiment 1. However, a correction operation is started when n minutes (which can be designated by the user in S101 and the like) elapsed after the probe 15 and the sample 27 are in contact with each other. The reason for this is as follows.

When the upward retraction of the probe 15 is started, there is also a risk that the contact between the probe 15 and the sample 27 is lost. Therefore, the initial position of the probe 15 is adjusted in advance for the first n minutes after the contact between the probe 15 and the sample 27 such that the contact is not lost even when the probe 15 drifts. Accordingly, since there is no risk that the contact is lost for the first n minutes, there is an advantage that a measurement value by the probe 15 can be reliably obtained. However, it is necessary to set the initial position within a range in which sufficient measurement accuracy is obtained even when drift occurs in the n minutes. For the same reason, even in the case of cooling the sample 27 described later, the correction operation is started after the elapse of n minutes.

### Embodiment 3

In Embodiment 3 of the invention, a procedure for determining a drift correction value in a case where measurement is performed after cooling the sample 27 will be described. Since the configuration of the charged particle beam device 100 is the same as that of Embodiment 1, a method for obtaining a correction value during cooling will be mainly described below.

During cooling, in addition to the drift due to the creep phenomenon at the room temperature, drift due to mechanical strain caused by cooling is also corrected. The drift due to the mechanical strain caused by cooling occurs in the Z-axis upward direction in the probe 15, and occurs in the Z-axis downward direction in the sample stand drive unit 19. Therefore, the drift occurs in a direction in which the probe 15 moves away from a portion to be inspected. When the drift amount exceeds the range of the portion to be inspected, the contact between the probe and the portion to be inspected is lost. The correction value is determined such that the tip end of the probe keeps contact for the measurement time T determined by the user within the range of the portion to be inspected.

A drift amount of the sample stand drive unit 19 in the certain time interval of t seconds in the Z-axis downward direction due to cooling is Δs, and a measurement time is T. The tip end of the probe drifts in a backward direction by (Δp+Δs) in each certain time interval of t seconds. Therefore, after n minutes have elapsed from the contact of the probe with the portion to be inspected, the probe is moved forward in the Z-axis downward direction (brought closer to the sample 27) by (Δp+Δs+c) in each time interval of t seconds. c is a correction value for preventing the contact from being lost due to an insufficient amount of advance of the probe.

### Embodiment 4

In Embodiment 4 of the invention, an operation example, in which an electrical characteristic of a sample is actually measured after determining a correction amount of the probe 15, will be described. A procedure for determining the correction amount is the same as in Embodiments 1 to 3. A configuration of the charged particle beam device 100 is similar to that in Embodiment 1.

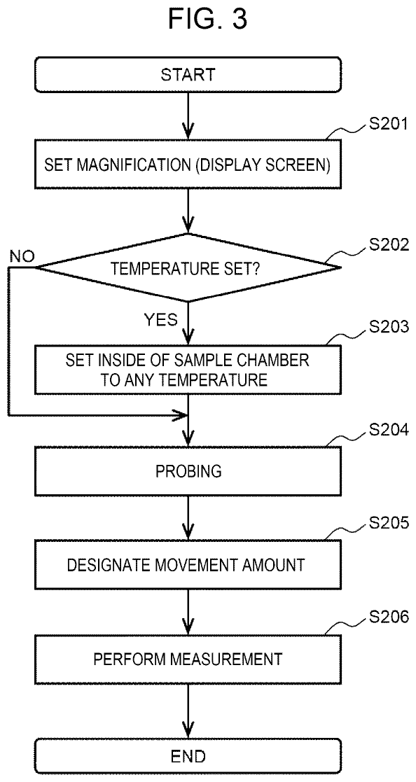

FIG. 3 is a flowchart showing a procedure for measuring an electrical characteristic of a sample. Hereinafter, steps in FIG. 3 will be described.

### (FIG. 3: Steps S201 to S204)

When the charged particle beam device 100 is activated, the charged particle beam device 100 enters a setting magnification waiting state of the SEM image, and a magnification setting input unit is displayed on a display screen associated with the control computer 23 (S201). A temperature in the sample chamber is set as necessary (S202: YES, S203), and when measurement is performed at the room temperature (S202: NO), the processing skips to S203. The probe 15 is brought into contact with a portion to be inspected (S204). These steps are the same as S101 to S104.

### (FIG. 3: Steps S205 to S206)

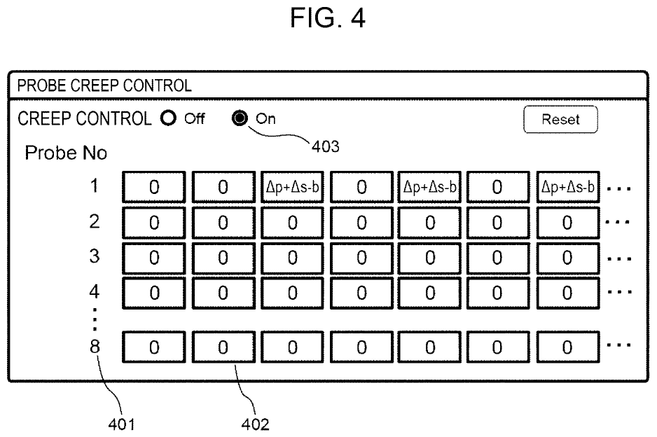

The control computer 23 displays a screen of FIG. 4 described later. The user designates a movement amount and a correction value for correcting the drift of the probe 15 on the same screen (S205). When the user input is completed, the sample 27 is measured using the designated movement amount and correction value (S206).

FIG. 4 is an example of a screen of the user interface provided by the control computer 23 in S205. The control computer 23 performs the flowchart of FIG. 2 in advance to calculate the movement amount (here, the movement amount Δp+Δs−b of Embodiment 2 is exemplified) for the drift correction in advance. When this screen is displayed, the movement amount can be presented as a preset value.

This screen includes a plurality of text boxes 402. A horizontal axis of an array of the text boxes corresponds to a time axis, and a vertical axis corresponds to a probe number 401. The control computer 23 sets the movement amount calculated in advance in the text boxes 402 corresponding to a correction timing designated by the user (every t seconds after the elapse of n minutes in Embodiments 2 to 3). The user can further change the movement amount by manual input. Accordingly, it is possible to cope with a slight change in the drift amount of the probe due to an environment caused by a temperature and the like during measurement.

### Modifications of Invention

In the above embodiments, the use of the piezoelectric element as the actuator of the probe unit 17 and the correction of the creep drift of the piezoelectric element have been described. In a case where an actuator other than the piezoelectric element is used as well, when the same drift occurs, the drift can be corrected using the same movement amount as in the above embodiments.

In Embodiment 1, it has been described that the drift amount is measured every minute and the movement amount that offsets the drift amount is obtained, but this is an example, and the time interval can be appropriately determined according to a characteristic of the probe 15, a measurement environment, and the like. Similarly, numerical values and time units such as t seconds and n minutes are also examples, and a longer or shorter time unit (for example, drift correction is performed every t minutes, and drift correction is started after n seconds have elapsed) may be adopted.

In the above embodiments, the correction value a to the correction value c for preventing the contact between the probe 15 and the sample 27 from being lost may not be necessarily used as long as the contact is unlikely to be lost. For example, when the accuracy of the movement amount for the drift correction is sufficiently high, the correction value may not be used. A radio button 403 in FIG. 4 can be used to designate whether to use the correction values a to c.

### REFERENCE SIGNS LIST

10: electron gun
11: separation wall
12: primary electron beam
13: secondary electron detector
14: secondary electron beam
15: probe
16: probe holder
17: probe unit
18: sample stand
19: sample stand drive unit
20: large sample stage
21: base
22: electrical characteristic measurement instrument
23: control computer
24: storage unit
25: electron gun controller
26: operator operation unit
27: sample
28: camera
29: camera
30: heating unit
31: cooling unit

1.-10. (canceled)

11. A measurement method for measuring an electrical characteristic of a sample, which is to be observed using a charged particle beam device, by using a probe by bringing the probe into contact with the sample, the measurement method comprising:
a step of measuring, by the charged particle beam device, a displacement of the probe generated under a temperature condition when the measurement is performed;
a step of specifying a movement amount by which the probe is moved to offset the displacement; and
a step of measuring the electrical characteristic while offsetting the displacement by using the specified movement amount when the electrical characteristic is measured by bringing the probe into contact with the sample, wherein
the step of specifying the movement amount is performed in advance by measuring the displacement of the probe by the charged particle beam device in advance before the step of measuring the electrical characteristic, and
in the step of measuring the electrical characteristic, the electrical characteristic is measured while offsetting the displacement by using the movement amount specified in advance without using information on a current position of the probe.

12. The measurement method according to claim 11, wherein
in the step of measuring the displacement, the displacement is measured at each of predetermined time intervals, and
in the step of specifying the movement amount, the movement amount is calculated by summing the displacement at each of the predetermined time intervals over a time length elapsed after the probe comes into contact with the sample.

13. The measurement method according to claim 12, wherein
the displacement includes a creep displacement caused by distortion of an actuator that drives the probe, and
when the step of measuring the electrical characteristic without heating or cooling the sample is performed,
in the step of specifying the movement amount, the movement amount by which the creep displacement is capable of being offset is specified at each of the predetermined time intervals, and
in the step of measuring the electrical characteristic, the electrical characteristic is measured, after the probe is retracted above the sample, using the movement amount calculated by the summing at a time point when the time length elapses after the probe comes into contact with the sample.

14. The measurement method according to claim 13, further comprising
a step of acquiring a first correction amount for avoiding loss of contact between the probe and the sample due to upward retraction of the probe in the step of measuring the electrical characteristic, wherein
when the step of measuring the electrical characteristic without heating or cooling the sample is performed, the step of measuring the electrical characteristic includes
a step of retracting the probe above the sample using a first corrected movement amount obtained by subtracting the first correction amount from the movement amount calculated by the summing at a time point when the time length elapses, and
a step of moving the probe downward using the movement amount for offsetting the creep displacement generated by the first corrected movement amount at a time point when the predetermined time interval further elapses from the time point when the time length elapses.

15. The measurement method according to claim 11, wherein
the displacement includes a first displacement caused by a strain of an actuator that drives the probe and a second displacement caused by thermal drift generated by heating the probe, and
when the step of measuring the electrical characteristic is performed after the sample is heated,
in the step of specifying the movement amount, the movement amount by which the first displacement and the second displacement are capable of being offset is specified at each of predetermined time intervals, and
in the step of measuring the electrical characteristic, at a time point when a predetermined time elapses after the probe comes into contact with the sample, the electrical characteristic is measured while the probe is retracted above the sample using the movement amount at each of the predetermined time intervals.

16. The measurement method according to claim 15, further comprising:
a step of acquiring a second correction amount for avoiding loss of contact between the probe and the sample due to upward retraction of the probe in the step of measuring the electrical characteristic, wherein
when the step of measuring the electrical characteristic is performed after the sample is heated,
in the step of measuring the electrical characteristic, the electrical characteristic is measured while the probe is retracted above the sample using a second corrected movement amount obtained by subtracting the second correction amount from the movement amount at each of the predetermined time intervals.

17. The measurement method according to claim 11, wherein
the displacement includes a first displacement caused by a distortion of an actuator that drives the probe and a third displacement caused by thermal drift generated by cooling the probe, and
when the step of measuring the electrical characteristic is performed after the sample is cooled,
in the step of specifying the movement amount, the movement amount by which the first displacement and the third displacement are capable of being offset is specified at each of predetermined time intervals, and
in the step of measuring the electrical characteristic, at a time point when a predetermined time elapses after the probe comes into contact with the sample, the electrical characteristic is measured while moving the probe in a direction approaching the sample using the movement amount at each of the predetermined time intervals.

18. The measurement method according to claim 17, further comprising:
a step of acquiring a third correction amount for avoiding loss of contact between the probe and the sample due to shortage of an amount by which the probe approaches the sample in the step of measuring the electrical characteristic, wherein
when the step of measuring the electrical characteristic is performed after the sample is cooled,
in the step of measuring the electrical characteristic, the electrical characteristic is measured while moving the probe in a direction approaching the sample by using a third corrected movement amount obtained by adding the third correction amount to the movement amount at each of the predetermined time intervals.

19. The measurement method according to claim 11, further comprising:
a step of individually specifying the movement amount for each of the plurality of probes, wherein
in the step of measuring the electrical characteristic, the electrical characteristic is measured while offsetting the displacement of the probe by applying the individual movement amount to the probe.

20. A charged particle beam device that observes a sample by irradiating the sample with a charged particle beam, the charged particle beam device comprising:
a probe configured to come into contact with the sample and measure an electrical characteristic of the sample; and
a control device configured to move a stage on which the sample is mounted, wherein the control device performs
a step of measuring, by the charged particle beam, a displacement of the probe generated under a temperature condition when the observation is performed,
a step of specifying a movement amount by which the probe is moved to offset the displacement, and
a step of measuring the electrical characteristic while offsetting the displacement by using the specified movement amount when the electrical characteristic is measured by bringing the probe into contact with the sample,
the control device performs the step of specifying the movement amount in advance by measuring the displacement of the probe in advance before the step of measuring the electrical characteristic, and
the control device measures the electrical characteristic while offsetting the displacement by using the movement amount specified in advance without using information on a current position of the probe in the step of measuring the electrical characteristic.
